(19) United States
(12) Patent Application Publication
(10) Pub. No.: US 2024/0341075 A1
(43) Pub. Date: Oct. 10, 2024

(54) SEMICONDUCTOR MEMORY DEVICES WITH IMPROVED PERFORMANCE

(71) Applicant: Taiwan Semiconductor Manufacturing Company, Ltd., Hsinchu (TW)

(72) Inventors: Peng-Chun Liou, Hsinchu City (TW); Ya-Yun Cheng, Hsinchu City (TW); Chia-En Huang, Hsinchu City (TW); Yi-Ching Liu, Hsinchu City (TW); Zhiqiang Wu, Hsinchu City (TW); Yih Wang, Hsinchu City (TW)

(73) Assignee: Taiwan Semiconductor Manufacturing Company, Ltd., Hsinchu (TW)

(21) Appl. No.: 18/296,010

(22) Filed: Apr. 5, 2023

(51) Int. Cl. H10B 12/00

(52) U.S. Cl. CPC H10B 12/00

(57) ABSTRACT

A semiconductor device includes a conductive layer extending along a first lateral direction; a gate dielectric layer disposed over the conductive layer; a channel layer disposed over the gate dielectric layer and extending along a second lateral direction perpendicular to the first lateral direction; a first via-like structure, in direct contact with the channel layer, that is disposed along a first edge of the first channel extending along the second lateral direction; and a second via-like structure, in direct contact with the channel layer, that is disposed along a second, opposite edge of the first channel extending along the second lateral direction. The first via-like structure and second via-like structure are laterally separated apart along a third lateral direction that is clockwise tilted from the second lateral direction with a first positive angle.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a diagram of a memory device, in accordance with some embodiments.

FIG. 2 illustrates a schematic diagram of a portion of a memory array, in accordance with some embodiments.

FIG. 3 illustrates a perspective view of a portion of a memory array, in accordance with some embodiments.

FIG. 4 illustrates a side view of a portion of the memory array of FIG. 3, in accordance with some embodiments.

FIG. 5 illustrates example waveforms presented by the memory array of FIG. 3, in accordance with some embodiments.

FIG. 6 illustrates an example layout of a portion of the memory array of FIG. 3, in accordance with some embodiments.

FIGS. 7 and 8 illustrate cross-sectional views of a portion of the memory array of FIG. 3, in accordance with some embodiments.

FIGS. 9, 10, 11, 12, 13, 14, 15, 16, 17, 18, 19, 20, 21, 22, 23, and 24 illustrate other example layouts of a portion of a memory array similar to the memory array of FIG. 3, in accordance with some embodiments.

FIG. 25 is an example flow chart of a method for fabricating a memory device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In general, a semiconductor device can include a number of active/passive device features that collectively or respectively function as a logic circuit (e.g., transistors, capacitors, resistors, etc.), which are formed along the major surface of a semiconductor substrate. A number of dielectric layers (sometimes referred to as intermetal dielectric (IMD) layers) can be formed over such device features to embed a number of interconnect structures (e.g., conductive lines, vias) to electrically connect those device features. The IMD layer, with interconnect structures embedded therein, is sometimes referred to as a metallization layer. Those device features formed along the major surface of the semiconductor substrate are typically referred to as part of front-end-of-line (FEOL) networking/processing, and those metallization layers formed over the device features are typically referred to as part of back-end-of-line (BEOL) networking/processing.

With the continually increasing device densities achieved by modern day semiconductor manufacturing processes, developments have been proposed to fabricate memory devices in the BEOL processing for certain applications (e.g., compute-in-memory (CIM) circuits). For example, a memory device including each of its memory cells, formed of one or more transistors and one serially connected capacitor in the BEOL processing, has been proposed. Such a BEOL memory device typically has a number of continuously extending metal layer that serves as respective gate terminals of the transistors, and a number of continuously extending semiconductor layers that are disposed over the metal layers and serve as respective channels of the transistors. Further above the semiconductor layers, a number of slot-like metal layers are formed to serve as respective source terminals and drain terminals of the transistors.

However, with each memory cell having one transistor and multiple memory cells sharing the same channel, leakage across different memory cells may become a critical issue. In this regard, other approaches have been proposed to arrange two transistors to connect in parallel. Specifically, each of these memory cells may have its own source terminal interposed between its pair of drain terminals, while the drain terminals may be shared with neighboring memory cells. With this arrangement, other issues may arise. For example, a spacing between neighboring drain terminals may become increasingly smaller (as a density of the memory cells increases), which can disadvantageously increase the coupling capacitance between neighboring memory cells. As a result, a read margin of the memory cell can be significantly reduced. Thus, the existing technologies regarding BEOL memory devices have not been entirely satisfactory in some aspects.

The present disclosure provides various embodiments of a BEOL memory device, and methods of forming the same. For example, the BEOL memory device, as disclosed herein, include a number of memory cells arranged as a memory array having plural columns and plural rows intersecting with each other. Along a first lateral direction (e.g., each row of the memory array), a number of metal layers are arranged in parallel with one another; and along a second lateral direction (e.g., each column of the memory array), a number of semiconductor layers are disposed over the metal layers and arranged in parallel with one another. Further above each of the semiconductor layers, the disclosed BEOL memory device includes a number of via-like structures, which allows these via-like structures to be laterally arranged in a zig-zag manner over the corresponding semiconductor layer. For example, the via-like structures can form a line or course having alternate right and left turns.

In accordance with various embodiments of the present disclosure, each of the memory cells may be operatively formed by two transistors and one capacitor (sometime referred to as a “2-transistor-1-capacitor (2T1C)” configuration). The two transistors may be connected to each other in parallel, and commonly connected to the capacitor in series. The two transistors may be formed at least by a corresponding one of the bottom metal layers, a portion of a corresponding one of the semiconductor layers, a corresponding set (e.g., 3) of the via-like structures. Specifically, the bottom metal layer can serve as a common gate terminal of those two transistors (which can be connected to or itself serve as a word line (WL)), the portion of the semiconductor layer can serve as respective channels of those two transistors, one of the three via-like structures can serve as a common source terminal of those two transistors (which can be connected to its corresponding capacitor), and two of the three via-like structures can serve as respective drain terminals of those two transistors (which can be connected to a bit line (BL)). With the drain terminals and source terminal arranged in the zig-zag manner (e.g., the drain terminals disposed along one side of the channel along its longitudinal direction and the source terminals disposed along the other side of the channel), a spacing between the drain terminals of different memory cells formed of respective semiconductor layers can be significantly increased. As such, the coupling capacitance between neighboring memory cells can be advantageously reduced.

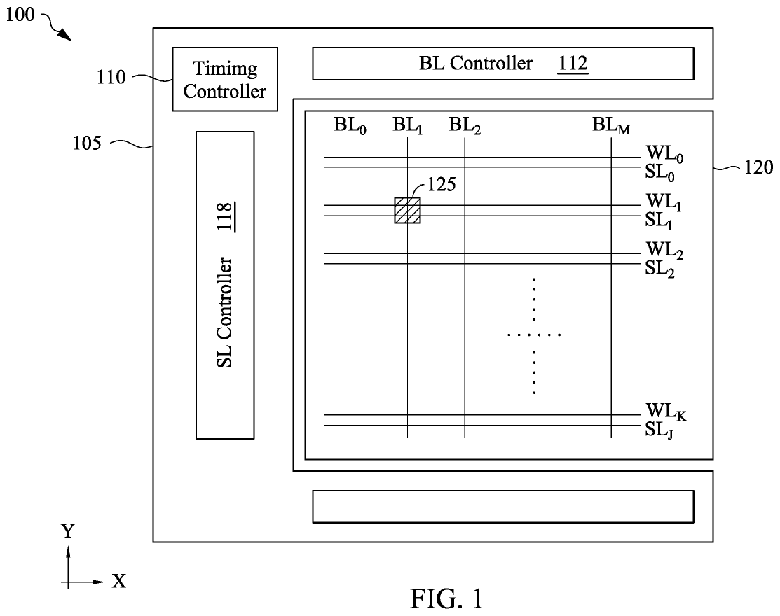

FIG. 1 illustrates a diagram of a memory device 100 (or memory system 100), in accordance with one embodiment. In some embodiments, the memory device 100 includes a memory controller 105 and a memory array 120. The memory array 120 may include a plurality of storage circuits or memory cells 125 arranged in two or three dimensional arrays. Each memory cell 125 may be coupled to a corresponding word line (WL), a corresponding bit line (BL), and a corresponding source line (SL). The memory controller 105 may write data to or read data from the memory array 120 according to electrical signals through word lines WL, bit lines BL, and source lines SL. In other embodiments, the memory device 100 includes more, fewer, or different components than shown in FIG. 1.

The memory array 120 is a hardware component that stores data. In one aspect, the memory array 120 is embodied as a semiconductor memory device. The memory array 120 includes a plurality of storage circuits or memory cells 125. The memory array 120 includes source lines SL0, SL1 . . . . SLJ, each extending in a first direction (e.g., the X-direction), word lines WL0, WL1 . . . . WLK, each extending in the first direction, and bit lines BL0, BL1 . . . . BLM, each extending in a second direction (e.g., the Y-direction). The source lines SL, the word lines WL and the bit lines BL may be conductive metals or metal layers (as will be discussed below). In one aspect, each memory cell 125 is coupled to a corresponding word line WL, a corresponding bit line BL, and a corresponding source line SL, and can be operated according to voltages or currents through the corresponding word line WL, the corresponding bit line BL, and the corresponding source line SL. Each memory cell 125 may include a volatile memory, a non-volatile memory, or a combination of them. In some embodiments, the memory array 120 includes additional lines (e.g., reference lines, reference control lines, power rails, etc.).

The memory controller 105 is a hardware component that controls operations of the memory array 120. In some embodiments, the memory controller 105 includes a bit line controller 112, a word line controller 114, a source line controller 118, and a timing controller 110. The bit line controller 112, the word line controller 114, the source line controller 118, and the timing controller 110 may be embodied as logic circuits, analog circuits, or a combination of them. In one configuration, the word line controller 114 is a circuit that provides a voltage or current through one or more word lines WL of the memory array 120. The bit line controller 112 is a circuit that provides or senses a voltage or current through one or more bit lines BL of the memory array 120, and the source line controller 118 is a circuit that provides or senses a voltage or current through one or more source lines SL of the memory array 120. In one configuration, the timing controller 110 is a circuit that provides control signals or clock signals to synchronize operations of the bit line controller 112, the word line controller 114, and the source line controller 118. The bit line controller 112 may be coupled to bit lines BL of the memory array 120, the word line controller 114 may be coupled to word lines WL of the memory array 120, and the source line controller 118 may be coupled to source lines SL of the memory array 120. In some embodiments, the memory controller 105 includes more, fewer, or different components than shown in FIG. 1.

The timing controller 110 can determine a selected memory cell 125 from a plurality of memory cells in the memory array 120, and cause the bit line controller 112, the word line controller 114, and the source line controller 118 to apply different voltages to selected lines and unselected lines. A selected line may be a line coupled to a selected memory cell, where an unselected line may be a line not coupled to the selected memory cell. Data can be programmed to the selected memory cell 125 or data stored by the selected memory cell 125 can be accessed by applying specific voltages to a selected bit line, a selected source line, and a selected word line.

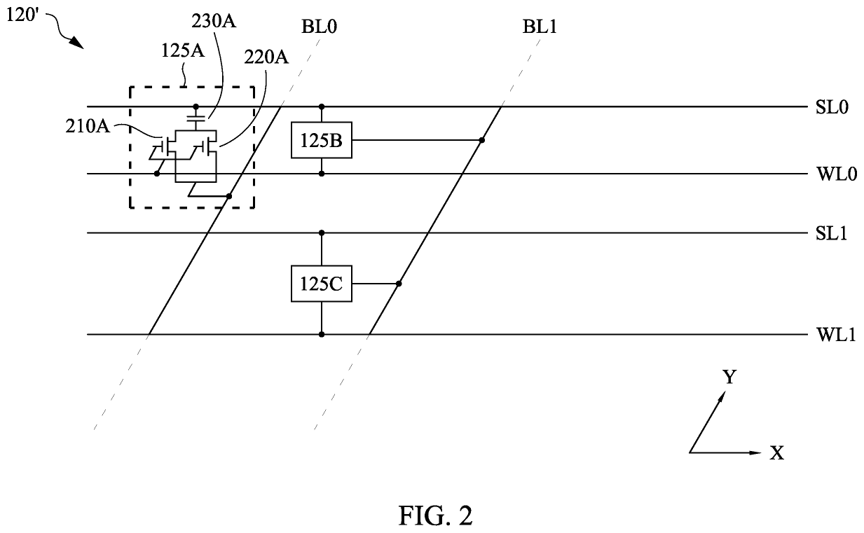

FIG. 2 illustrates a schematic diagram of a memory array 120′, in accordance with various embodiments of the present disclosure. The memory array 120′ may be a portion of the memory array 120 in FIG. 1. The memory array 120′ may include an array of memory cells 125 (e.g., 125A, 125B, 125C). The memory array 120′ may also include source lines SL0 . . . SL1 extending along a first direction (e.g., the X-direction), bit lines BL0 . . . BL1 extending along a second direction (e.g., the Y-direction), and word lines WL0 . . . WL1 extending along the first direction (e.g., the X-direction).

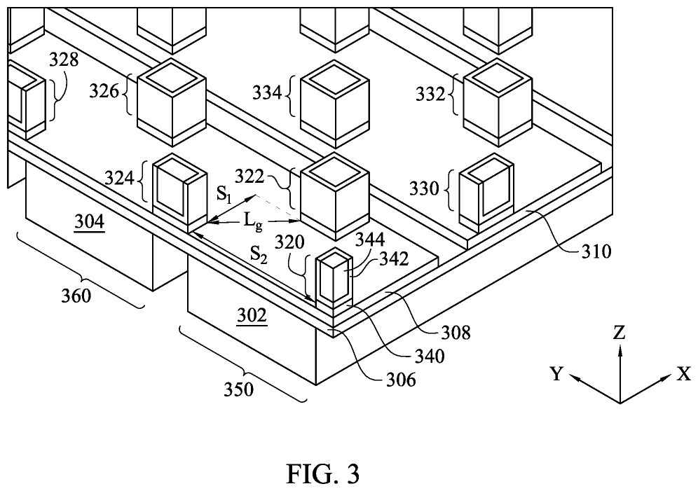

Each memory cell 125 may include a pair of transistors and a capacitor. The two transistors, which are connected to each other in parallel, may be connected to the capacitor in series. The two transistors may operatively serve as select or access transistors for the memory cell, and the capacitor may operatively serve as a storage element for the memory cell. In accordance with various embodiments, those two access transistors and the storage capacitor may all be formed in the BEOL processing. For example, the access transistors may each be formed as a back-gate transistor having its gate terminal disposed on a backside of its channel and its drain and source terminal disposed on a frontside of the channel (which will be shown below, e.g., in FIG. 3), and the storage capacitor may be formed as a metal-insulator-metal (MIM) structure (which will be shown below, e.g., in FIG. 8). Further, each memory cell 125 is connected to a corresponding set of a word line WL, a bit line BL, and a source line SL.

As a non-limiting example, the memory cell 125A includes transistors 210A and 220A, and a capacitor 230A. In one configuration, a first end of the memory cell 125A is coupled to a corresponding bit line BL (e.g., BL0), a second end of the memory cell 125A is coupled to a corresponding word line WL (e.g., WL0), and a third end of the memory cell 125A is coupled to a corresponding source line SL (e.g., SL0). Specifically, respective gate terminals of the transistors 210A and 220A are commonly connected to the word line WL0; respective drain terminals of the transistors 210A and 220A are commonly connected to the bit line BL0; and respective source terminals of the transistors 210A and 220A are commonly connected to the source line SL0 through the capacitor 230A. Each of the other memory cells (e.g., 125B, 125C) may be configured similarly to the memory cell 125A as illustrated in FIG. 2, and thus, the description will not be repeated.

FIG. 3 illustrates a perspective view of a memory device 300, in accordance with various embodiments of the present disclosure. The memory device 300 may be a portion of an implementation of the memory array including a number of memory cells (each of which includes two access transistors and one storage capacitor), as discussed above (e.g., 120′). According to various embodiments of the present disclosure, the memory device 300 is formed in the BEOL processing. That is, each element/feature of the memory device 300 is formed in one or more metallization layers disposed above a number of (e.g., logic) transistors that are formed along the major surface of a semiconductor substrate.

It should be understood that the perspective view of FIG. 3 is simplified, and thus, it should be understood that any of various other features/components can also be included in FIG. 3, while remaining within the scope of the present disclosure. For example, corresponding storage capacitors of the memory cells are not shown; and a number of metal layers (or interconnect structures in the BEOL processing) formed over the memory device 300 configured as the BLs and SLs are not shown either.

As shown, the memory device 300 includes a number of conductive layers 302 and 304, a dielectric layer 306, a number of semiconductor layers 308 and 310, and a number of contact structures 320, 322, 324, 326, 328, 330, 332, and 334. The conductive layers 302 and 304, each of which may be formed as one conductive line of a corresponding metallization layer, may extend along a first lateral direction (e.g., the X-direction). The conductive layers 302 and 304, physically separated from each other, may be electrically isolated from each other through an inter-metal dielectric (IMD) material (e.g., silicon oxide or a low-k dielectric material) of the corresponding metallization layer. The conductive layers 302-304 can be formed of a suitable conductive material selected from the group consisting of: copper (Cu), tantalum nitride (TaN), titanium nitride (TiN), tungsten (W), aluminum (Al), poly silicon, and combinations thereof. The dielectric layer 306 may be universally disposed over the conductive layers 302-304. The dielectric layer 306 may be formed of at least one of the following materials: hafnium oxide (HfO₂), silicon oxide (SiO₂), aluminum oxide (Al₂O₃), silicon oxynitride (SiON), and combinations thereof. The semiconductor layers 308-310, which are physically separated from each other, may be formed over the dielectric layer 306. The semiconductor layers 308-310 may extend along a second lateral direction orthogonal to the first lateral direction (e.g., the Y-direction).

In one embodiment where the access transistors of the memory cells are configured in n-type, the semiconductor layers 308-310 may be formed of at least one of the following materials: indium gallium zinc oxide (IGZO), zinc oxide (ZnO), indium oxide (In₂O₃), tin oxide (SnO₂), and combinations thereof. In another embodiment where the access transistors of the memory cells are configured in p-type, the semiconductor layers 308-310 may be formed of at least one of the following materials: nickel oxide (NiO), copper oxide (Cu₂O), copper aluminum oxide (CuAlO₂), copper gallium oxide (CuGaO₂), copper indium oxide (CuInO₂), strontium copper oxide (SrCuO₂), tin oxide (SnO), and combinations thereof.

In various embodiments of the present disclosure, each of the contact structures 320-334 is formed as a via-like structure, and these contact structures 320-334 are disposed over a corresponding semiconductor layer to laterally arrange in a zig-zag manner. As shown, the contact structures 320, 324, and 328 are disposed along one side of the semiconductor layer 308 (extending in the Y-direction), while the contact structures 322 and 326 are disposed along the other side of the semiconductor layer 308 (extending in the Y-direction). Stated another way, a first group containing the contact structures 322 and 326 are spaced from a second group containing the contact structures 320, 324, and 328 along the X-direction with a first spacing, “S₁.” Further, each of the first group (e.g., the contact structures 322 and 326) is interposed between a corresponding pair of the second group (e.g., the contact structures 320 and 324) along the Y-direction, and spaced from any of the pair of the second group along the Y-direction with around one half of a second spacing, “S₂/2.”

As such, the contact structures over the semiconductor layer 308 (e.g., 320 to 328) can form a zig-zag course or line having alternate right and left turns. Specifically, the contact structures 322 and 320 form a first segment of the zig-zag course extending along a third lateral direction that is clockwise tilted from the Y-direction with a first positive angle; the contact structures 322 and 324 form a second segment of the zig-zag course extending along a fourth lateral direction that is counterclockwise tilted from the Y-direction with a second positive angle; the contact structures 324 and 326 form a third segment of the zig-zag course extending along the third lateral direction that is clockwise tilted from the Y-direction with the first positive angle; and the contact structures 326 and 328 form a fourth segment of the zig-zag course extending along the fourth lateral direction that is counterclockwise tilted from the Y-direction with the second positive angle; and so on. The first positive angle can be equal to the second positive angle, which can be an acute angle, in some embodiments. For example, the first and second angles may each be equal to about 45 degrees. Similarly, the contact structures formed over the semiconductor layer 310 (e.g., 330, 332, 334, etc.) can form another zig-zag course or line having alternate right and left turns.

Further, each of the contact structures 320 to 334 can include multiple portions protruding away from the corresponding (overlaid) semiconductor layer. Using the contact structure 320 (which has a cutaway view in FIG. 3) as a representative example, the contact structure 320 can have elevated portion 340, a bowl-shaped portion 342, and a contact portion 344. The elevated portion 340 can protrude from the semiconductor layer 308 as a mesa structure, e.g., having a relatively flat top surface elevated from a top surface of the semiconductor layer 308. The bowl-shaped portion 342, disposed over the top surface of such a mesa structure, can surround a bottom surface and sidewalls of the contact portion 344. In some embodiments, the semiconductor layer 308, the elevated portion 340, and the bowl-shaped portion 342 can be formed of the same semiconductor material, while in respective different doping concentrations. For example, a doping concentration of the bowl-shaped portion 342 is higher than a doping concentration of the elevated portion 340, which is higher than a doping concentration of the semiconductor layer 308. The contact portion 344 can be formed of a conductive material selected from the group consisting of: copper (Cu), tantalum nitride (TaN), titanium nitride (TiN), tungsten (W), aluminum (Al), ruthenium (Ru), cobalt (Co), poly silicon, and combinations thereof.

In various embodiments, each of the metal layers (e.g., 302), a portion of the dielectric layer (e.g., 306) overlaying the metal layer, a portion of the semiconductor layer (e.g., 308) overlaying the metal layer, and three corresponding ones of the contact structures (e.g., 320, 322, and 324) can form two access transistors of one memory cell of the memory device 300 (e.g., 210A and 220A of FIG. 2). For example, the metal layer 302 and the contact structure 322 may serve as a common gate terminal and a common source terminal of two access transistors of a first memory cell 350, respectively, while the contact structure 320 may serve as a drain terminal of one of these two access transistors and the contact structure 324 may serve as a drain terminal of the other of these two access transistors. The portion of dielectric layer 306 (overlaying the metal layer 302) and the portion of semiconductor layer 308 (overlaying the metal layer 302) may serve as channels and gate oxides of the two access transistors, respectively. As such, each of these two access transistors can have an effective channel length, labeled as “L_{g}” in FIG. 3.

A plural number of such memory cells may share the same semiconductor layer 308. For example, two access transistors of a second memory cell 360 can be formed by the metal layer 304, another portion of the dielectric layer 306, another portion of the semiconductor layer 308, and the contact structures 324 to 328. The metal layer 304 and the contact structure 326 may serve as a common gate terminal and a common source terminal of these two access transistors, respectively, while the contact structure 324 may serve as a drain terminal of one of these two access transistors and the contact structure 328 may serve as a drain terminal of the other of these two access transistors. Similarly, a plural number of memory cells can be formed over the semiconductor layer 310.

The gate terminals (e.g., metal layers 302-304) may each serve as or be connected to a word line WL. Further, the drain terminals of different memory cells may be coupled to one another through a bit line BL, while the source terminal of each memory cell may be coupled to a source line SL through a respective storage capacitor. As such, along the Y-direction (the longitudinal direction of the semiconductor layers 308-310), a number of memory cells can be arranged with respect to one another, and further, each of the memory cells along the same semiconductor layer can be coupled to a respective word line WL. The longitudinal direction of the semiconductor layers 308-310 (also a longitudinal direction of the bit line BL) may accordingly correspond to columns of the memory device 300, and the longitudinal direction of the metal layers 302-304 may accordingly correspond to rows of the memory device 300.

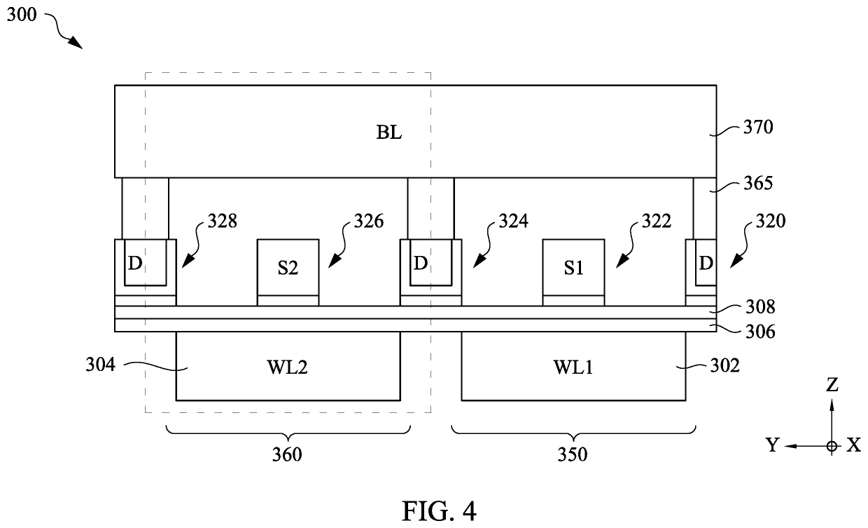

FIG. 4 illustrates a side view of a portion of the memory device 300 (FIG. 3), in accordance with various embodiments of the present disclosure. In the side view of FIG. 4, respective access transistors of the memory cells 350 and 360 are shown. Specifically, the metal layer 302 serves as a common gate terminal of the two access transistors of the memory cell 350 is labeled as “word line WL1,” the contact structure 322 serves as a common source terminal of the two access transistors of the memory cell 350 is labeled as “S1,” the metal layer 304 serves as a common gate terminal of the two access transistors of the memory cell 360 is labeled as “word line WL2,” and the contact structure 326 serves as a common source terminal of the two access transistors of the memory cell 360 is labeled as “S2.” The contact structures 320, 324, and 328 serving as drain terminals of the memory cells 350 and 360 may be coupled to a bit line BL 370 through respective via structures 365.

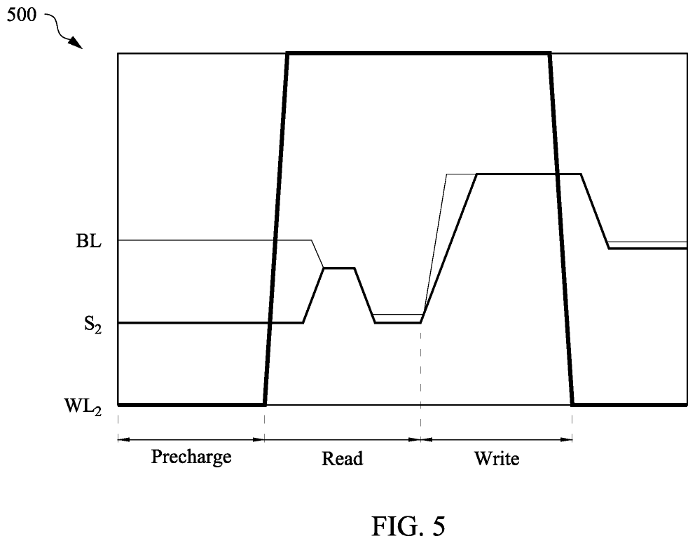

FIG. 5 illustrates an example waveform 500 associated with operation of the memory device 300 as shown in FIGS. 3-4. In the depicted embodiment, the selected memory cell 360 is allowed to be accessed by applying a logic high on the WL2 to turn on its access transistors, while the unselected memory cell 350 is not allowed to be accessed by applying a logic low on the WL1 to turn off its access transistors. Further, the BL 370 connected to the selected memory cell 360 and the unselected memory cell 350 is biased under various conditions to implement “precharge,” “read,” and “write” operations. During the read and write operations, the WL2 may be applied with a logic high; and during the precharge operation, the WL2 may be applied with a logic low.

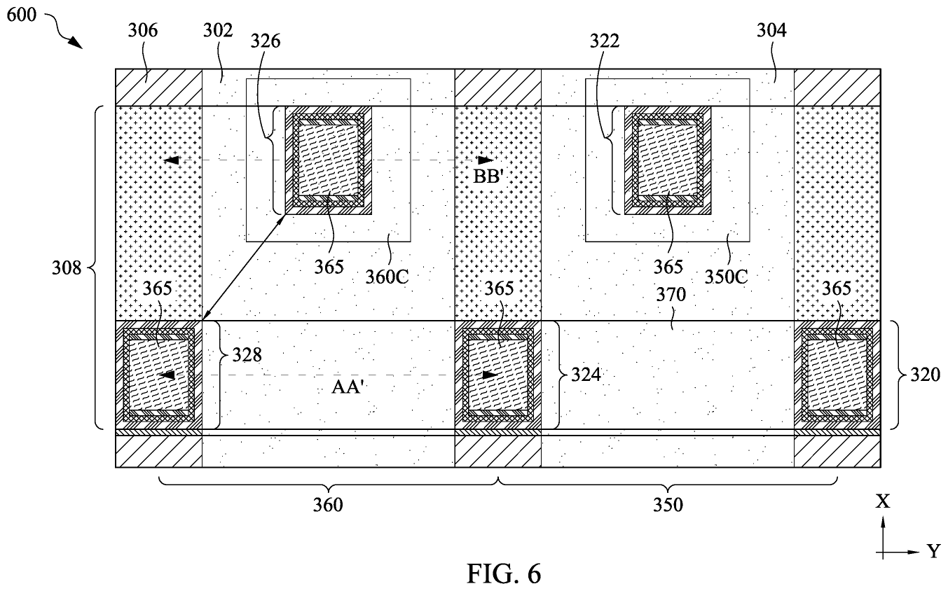

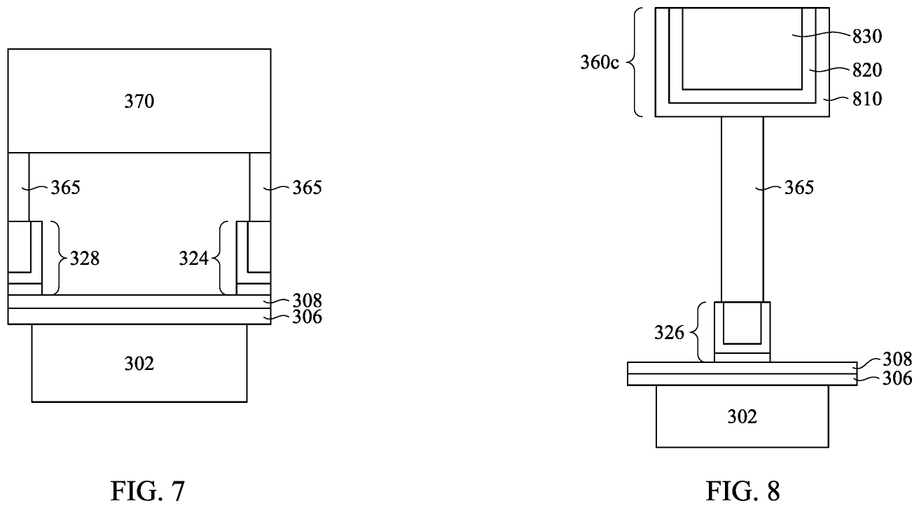

FIG. 6 illustrates an example layout 600 of the memory device 300 (FIGS. 3-4), in accordance with various embodiments of the present disclosure. Thus, some of the reference numerals of FIGS. 3-4 may be again used in the following discussion of layout 600. Corresponding to the layout 600 shown in FIG. 6, FIG. 7 and FIG. 8 respectively illustrate cross-sectional views of the memory device 300, in accordance with various embodiments of the present disclosure. Specifically, the cross-sectional view of FIG. 7 is cut along line AA′ indicated in FIG. 6; and the cross-sectional view of FIG. 8 is cut along line BB′ indicated in FIG. 6.

As shown in FIG. 6, the layout 600 includes patterns for the metal layers 302-304, the dielectric layer 306, the semiconductor layer 308, the contact structures 320-328, the via structures 365, the bit line BL 370, storage capacitor 350C of the memory cell 350, and storage capacitor 360C of the memory cell 360, respectively. In various embodiments, the contact structures 320 to 328 are each formed as a via-like structure, each of which further has different portions (e.g., an elevated portion, a bowl-shaped portion, and a contact portion). By being forming in such a via-like structure, these contact structures 320 to 328 can be arranged to form a zig-zag course, with a number of segments extending along a lateral direction either clockwise or counterclockwise tilted from the longitudinal direction of the semiconductor layer 308 (the Y-direction) with an acute angel (e.g., about 45 degrees).

With the arrangement of the contact structures 320 to 328, the bit line BL 370 can extend along the Y-direction to electrically connect a first set of the contact structures (e.g., 320, 324, 328, etc.), as shown in the cross-sectional view of FIG. 7. Each of a second set of the contact structures (e.g., 322, 326, etc.) can be connected to a respective storage capacitor, as shown in the cross-sectional view of FIG. 8. For example, the contact structure 322, which functions as a common source terminal of two access transistors of the memory cell 350, can connect those two access transistors to the storage capacitor 350C (in series). Similarly, the contact structure 326, which functions as a common source terminal of two access transistors of the memory cell 360, can connect those two access transistors to the storage capacitor 360C (in series).

In some embodiments, the storage capacitor of each of the memory cells may be formed in an MIM configuration. For example in FIG. 8, the storage capacitor 360C of the memory cell 360 includes a first electrode 810, a capacitor dielectric 820, and a second electrode 830, in which the capacitor dielectric 820 is interposed between the first electrode 810 and the second electrode 830. The first electrode 810 may be connected to the common source terminal 326 of the memory cell 360 through a corresponding via structure 365. The first electrode 810 and second electrode 830 may each be formed of a suitable conductive material selected from the group consisting of: copper (Cu), tantalum nitride (TaN), titanium nitride (TiN), tungsten (W), aluminum (Al), poly silicon, and combinations thereof. The capacitor dielectric 820 may be formed of at least one of the following materials: hafnium oxide (HfO₂), silicon oxide (SiO₂), aluminum oxide (Al₂O₃), silicon oxynitride (SiON), and combinations thereof.

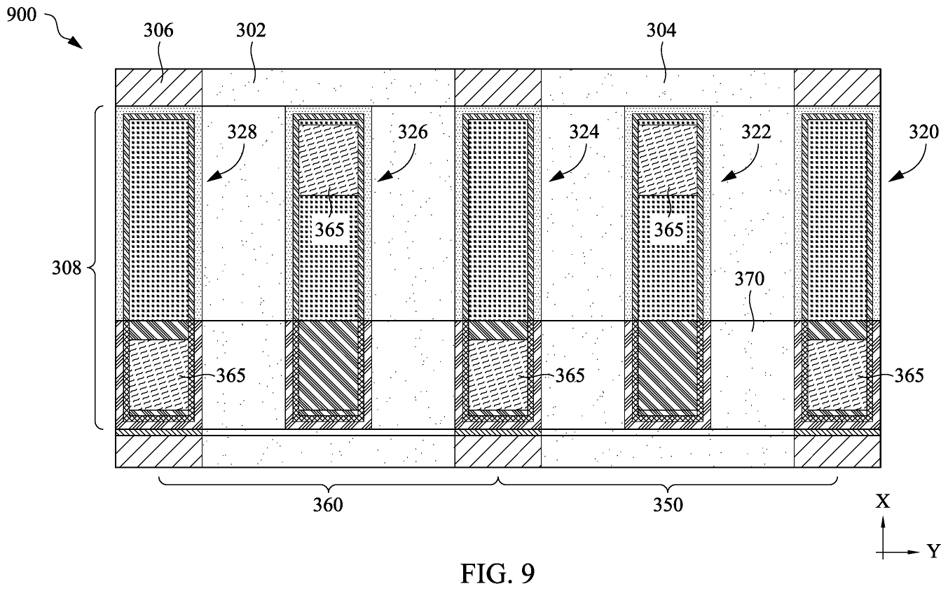

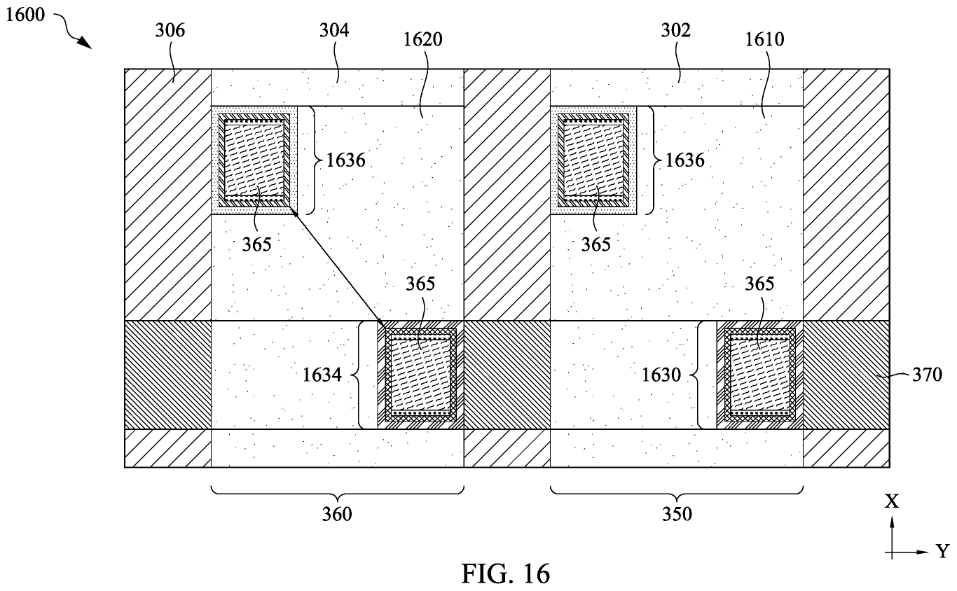

FIGS. 9, 10, 11, 12, 13, 14, 15, 16, 17, 18, 19, 20, 21, 22, 23, and 24 illustrate other example layouts 900, 1000, 1100, 1200, 1300, 1400, 1500, 1600, 1700, 1800, 1900, 2000, 2100, 2200, 2300, and 2400 of memory devices similar to the memory device 300 shown in FIGS. 3-4, respectively, in accordance with various embodiments of the present disclosure. In particular, the layouts 900 to 1500 (FIG. 9 to FIG. 15) may be directed to forming a memory device having each of its memory cells configured with two transistors and one capacitor (2TIC configuration), while the layouts 1600 to 2400 (FIG. 16 to FIG. 24) may be directed to forming a memory device having each of its memory cells configured with one transistor and one capacitor (1TIC configuration). Solely for purposes of clarity, some of the reference numerals of FIGS. 3-4 may be again used in the following discussion of layouts 900 to 2400, and the corresponding storage capacitors of these memory devices (formed based on the layouts 900 to 2400) are not shown.

Referring first to FIG. 9, the layout 900 is substantially similar to the layout 600 except that each of the contact structures 320 to 328 is formed as a slot-like structure. Such a slot-like structure may extend along the longitudinal direction of the metal layers 302-304 (i.e., the gate terminals of the memory cells 350-360). Further in FIG. 9, the contact structures 320 to 328 each extend from one side of the semiconductor layer 308 (along the Y-direction) to its other opposite side. With the contact structures 320 to 328 formed in such a slot-like configuration, their corresponding via structures 365 can still be formed in a zig-zag manner. For example, the via structure 365 in contact with the contact structure 320 and the via structure 365 in contact with the contact structure 322 form a first segment of the zig-zag course extending along a lateral direction clockwise tilted from the longitudinal direction of the semiconductor layer 308 (the Y-direction) with a first acute angel; the via structure 365 in contact with the contact structure 322 and the via structure 365 in contact with the contact structure 324 form a second segment of the zig-zag course extending along another lateral direction counterclockwise tilted from the longitudinal direction of the semiconductor layer 308 (the Y-direction) with a second acute angel; and so on.

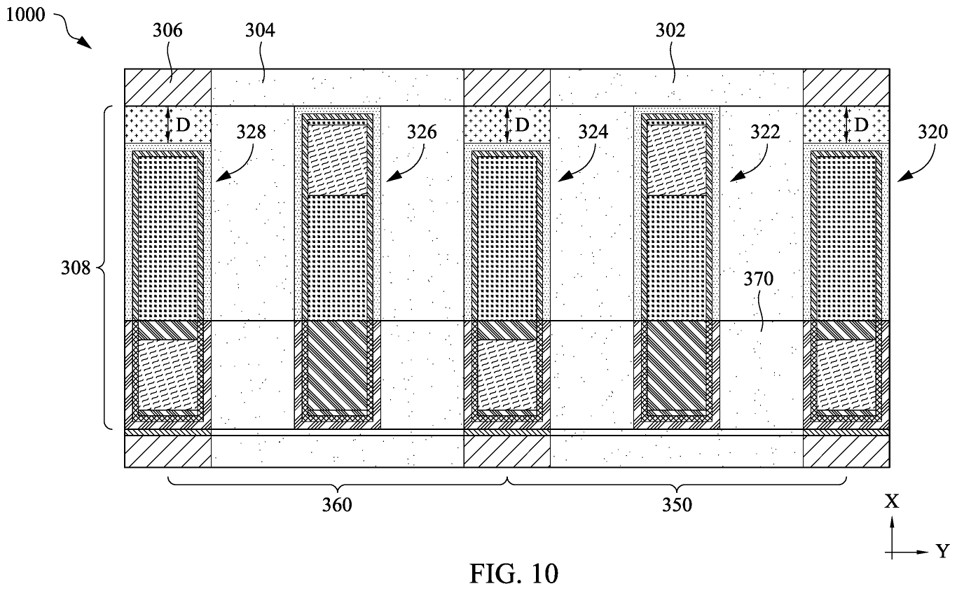

Referring next to FIG. 10, the layout 1000 is substantially similar to the layout 900 except that some of the slot-like contact structures 320 to 328 have shorter longitudinal length than others of the slot-like contact structures 320 to 328. Specifically, such shorter contact structures may each have at least one end not aligned with the side of the semiconductor layer 308. For example in FIG. 10, the contact structures 320, 324, and 328 are each formed shorter than any of the contact structures 322 and 326. Each of the contact structures 322 and 326 may extend from one side of the semiconductor layer 308 to its other opposite side, while each of the contact structures 320, 324, and 328 may extend from one side of the semiconductor layer 308 with a length that is less than a width of the semiconductor layer 308 (extending in the X-direction) by a distance “D.” Alternatively stated, one end of each of the contact structures 320, 324, and 328 is aligned with one side of the semiconductor layer 308, while its other end is shifted from the other side of the semiconductor layer 308 with a distance (D).

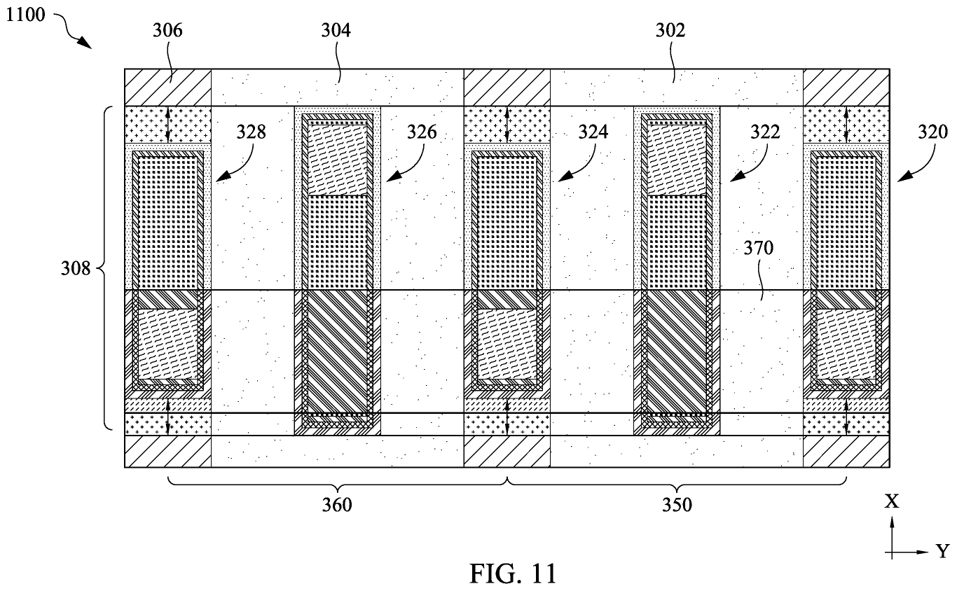

Referring next to FIG. 11, the layout 1100 is substantially similar to the layout 900 except that some of the slot-like contact structures 320 to 328 have shorter longitudinal length than others of the slot-like contact structures 320 to 328. Specifically, such shorter contact structures may each have at least one end not aligned with the side of the semiconductor layer 308. For example in FIG. 11, the contact structures 320, 324, and 328 are each formed shorter than any of the contact structures 322 and 326. Each of the contact structures 322 and 326 may extend from one side of the semiconductor layer 308 to its other opposite side, while each of the contact structures 320, 324, and 328 may extend along the X-direction with a length that is less than a width of the semiconductor layer 308 (extending in the X-direction) by a first distance “D₁” and a second distance “D₂.” Alternatively stated, one end of each of the contact structures 320, 324, and 328 is shifted from one side of the semiconductor layer 308 with a first distance (D₁), and its other end is shifted from the other side of the semiconductor layer 308 with a second distance (D₂).

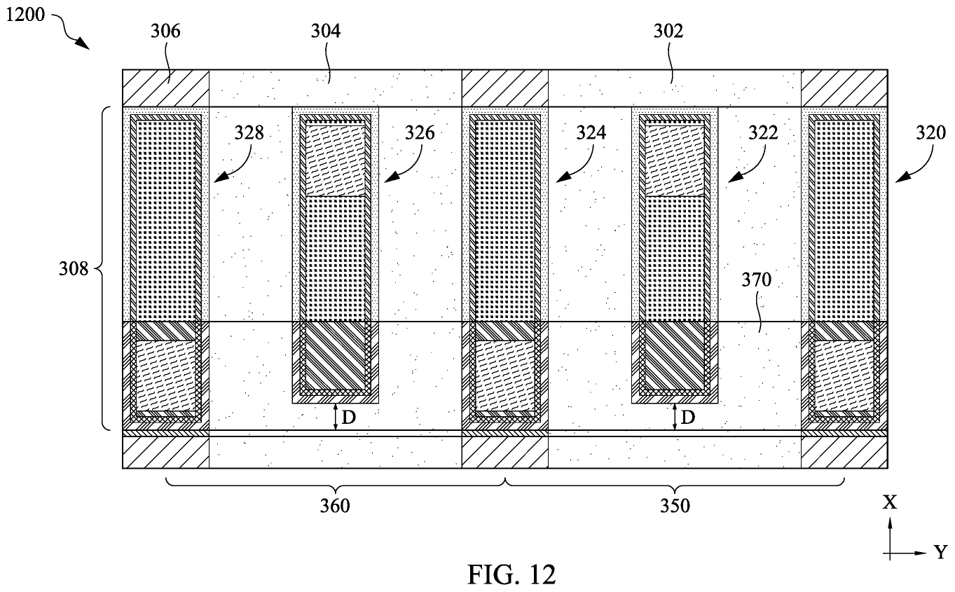

Referring next to FIG. 12, the layout 1200 is substantially similar to the layout 900 except that some of the slot-like contact structures 320 to 328 have shorter longitudinal length than others of the slot-like contact structures 320 to 328. Specifically, such shorter contact structures may each have at least one end not aligned with the side of the semiconductor layer 308. For example in FIG. 12, the contact structures 322 and 326 are each formed shorter than any of the contact structures 320, 324, and 328. Each of the contact structures 320, 324, and 328 may extend from one side of the semiconductor layer 308 to its other opposite side, while each of the contact structures 322 and 326 may extend from one side of the semiconductor layer 308 with a length that is less than a width of the semiconductor layer 308 (extending in the X-direction) by a distance “D.” Alternatively stated, one end of each of the contact structures 322 and 326 is aligned with one side of the semiconductor layer 308, while its other end is shifted from the other side of the semiconductor layer 308 with a distance (D).

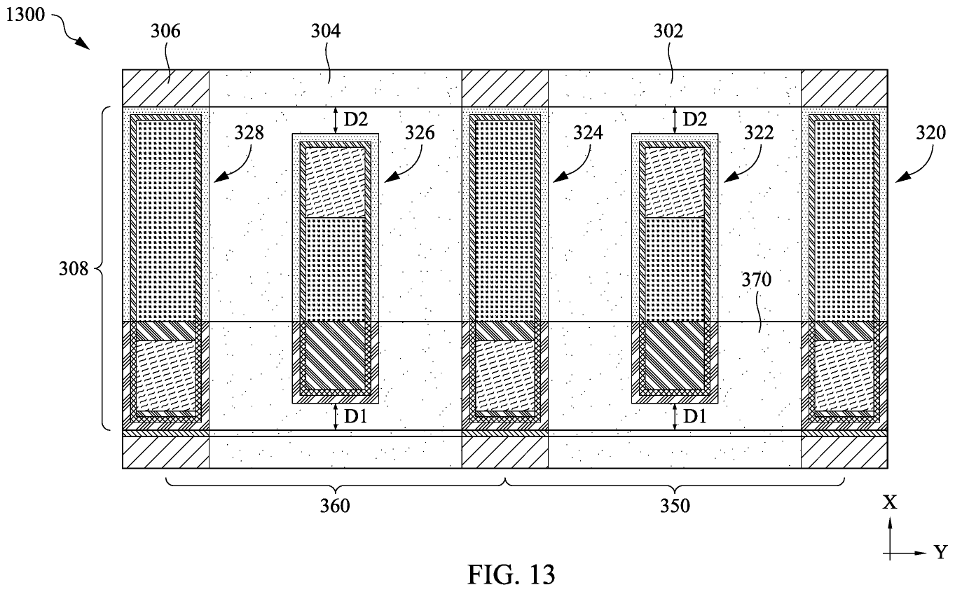

Referring next to FIG. 13, the layout 1300 is substantially similar to the layout 900 except that some of the slot-like contact structures 320 to 328 have shorter longitudinal length than others of the slot-like contact structures 320 to 328. Specifically, such shorter contact structures may each have at least one end not aligned with the side of the semiconductor layer 308. For example in FIG. 13, the contact structures 322 and 326 are each formed shorter than any of the contact structures 320, 324, and 328. Each of the contact structures 320, 324, and 328 may extend from one side of the semiconductor layer 308 to its other opposite side, while each of the contact structures 322 and 326 may extend along the X-direction with a length that is less than a width of the semiconductor layer 308 (extending in the X-direction) by a first distance “D₁” and a second distance “D₂.” Alternatively stated, one end of each of the contact structures 322 and 326 is shifted from one side of the semiconductor layer 308 with a first distance (D₁), and its other end is shifted from the other side of the semiconductor layer 308 with a second distance (D₂).

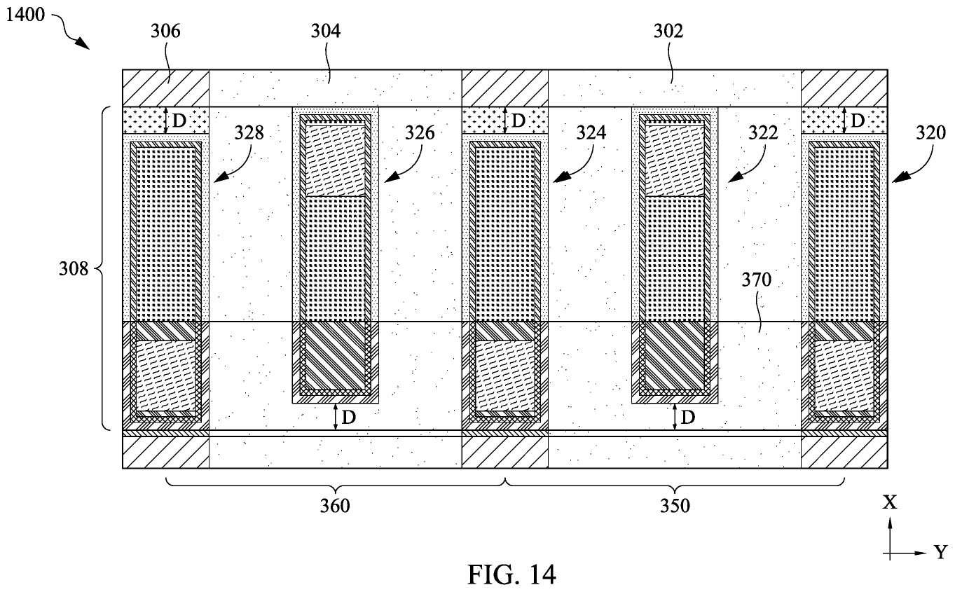

Referring next to FIG. 14, the layout 1400 is substantially similar to the layout 900 except that each of the slot-like contact structures 320 to 328 is formed shorter than the underlying semiconductor layer 308 along the X-direction. Specifically, such shorter contact structures may each have its one end not aligned with one side of the semiconductor layer 308, while the other end is aligned with the other side of the semiconductor layer 308. For example in FIG. 14, each of the contact structures 320 to 328 may extend from one side of the semiconductor layer 308 with a length that is less than a width of the semiconductor layer 308 (extending in the X-direction) by a distance “D.” Alternatively stated, one end of each of the contact structures 320 to 328 is aligned with one side of the semiconductor layer 308, while its other end is shifted from the other side of the semiconductor layer 308 with a distance (D).

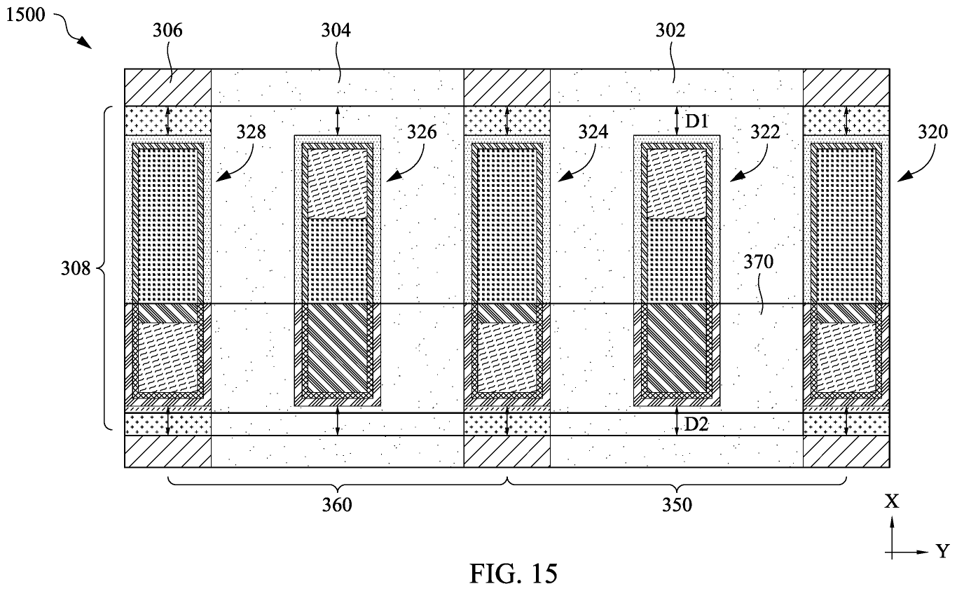

Referring next to FIG. 15, the layout 1500 is substantially similar to the layout 900 except that each of the slot-like contact structures 320 to 328 is formed shorter than the underlying semiconductor layer 308 along the X-direction. Specifically, such shorter contact structures may each have its both ends not aligned with any side of the semiconductor layer 308. For example in FIG. 15, each of the contact structures 320 to 328 may extend in the X-direction with a length that is less than a width of the semiconductor layer 308 (extending in the X-direction) by a first distance “D₁” and a second distance “D₂.” Alternatively stated, one end of each of the contact structures 320 to 328 is shifted from one side of the semiconductor layer 308 with a first distance (D₁), while its other end is shifted from the other side of the semiconductor layer 308 with a second distance (D₂).

Referring next to FIG. 16, similar to the layout 600 (FIG. 6), the layout 1600 also includes the metal layer 302-304 and the dielectric layer 306. However, the layout 1600 may include multiple semiconductor layers, e.g., 1610 and 1620, configured as channels of the memory cells 350 and 360, respectively. The semiconductor layers 1610 and 1620 may be separated from each other, and may overlay the metal layers 302 and 304, respectively. Further, the layout 1600 may include a less number of contact structures, but such contact structures may be similar to the via-like structure that has multiple portions (e.g., an elevated portion, a bowl-shaped portion, and a contact portion), as discussed above. For example, over the semiconductor layer 1610, the layout 1600 include contact structures 1630 and 1632; and over the semiconductor layer 1620, the layout 1600 include contact structures 1634 and 1636. The contact structures 1630 and 1632 may be shifted from each other along both the X-direction and the Y-direction; and similarly, the contact structures 1634 and 1636 may be shifted from each other along both the X-direction and the Y-direction.

In such a configuration, each of the memory cells 350-360 may include one access transistor connected to a corresponding storage capacitor (not shown) in series. For example, the memory cell 350 includes one access transistor, with the metal layer 302, the contact structure 1630, and the contact structure 1632 functioning as a gate terminal, a drain terminal, and a source terminal of the access transistor, respectively; and the memory cell 360 includes one access transistor, with the metal layer 304, the contact structure 1634, and the contact structure 1636 functioning as a gate terminal, a drain terminal, and a source terminal of the access transistor, respectively. Each of the drain terminals (e.g., 1630, 1634) and the source terminals (e.g., 1632, 1636) is connected to a corresponding via structure 365.

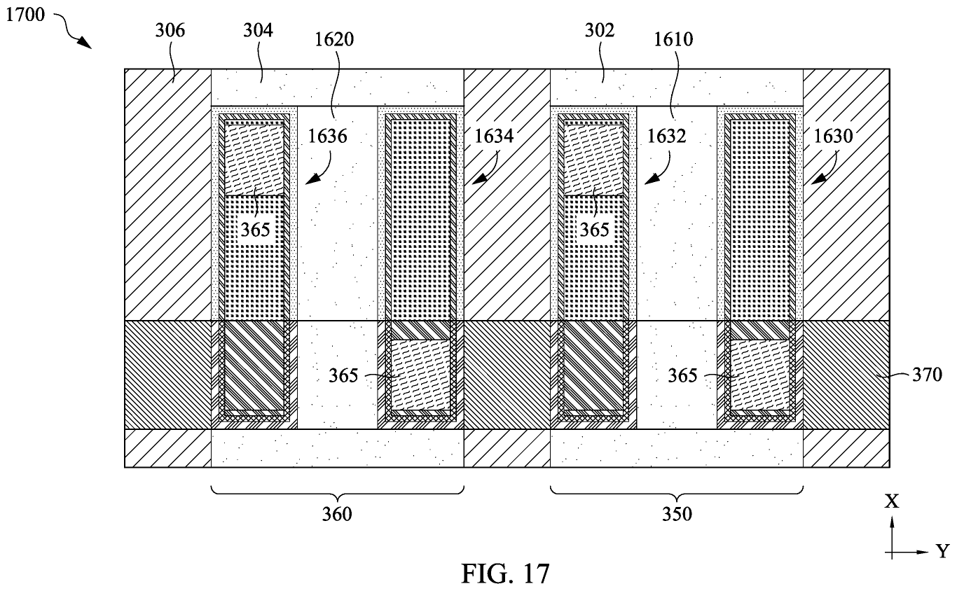

Referring next to FIG. 17, the layout 1700 is substantially similar to the layout 1600 except that each of the contact structures 1630 to 1636 is formed as a slot-like structure. Such a slot-like structure may extend along the longitudinal direction of the metal layers 302-304 (i.e., the gate terminals of the memory cells 350-360). Further in FIG. 17, the contact structures 1630 to 1636 each extend from one side of the semiconductor layer 1610 or 1620 (along the Y-direction) to its other opposite side. With the contact structures 1639 to 1636 formed in such a slot-like configuration, their corresponding via structures 365 can still be formed in a zig-zag manner. For example, the via structure 365 in contact with the contact structure 1630 and the via structure 365 in contact with the contact structure 1632 form a first segment of the zig-zag course extending along a lateral direction clockwise tilted from the Y-direction with a first acute angel; the via structure 365 in contact with the contact structure 1632 and the via structure 365 in contact with the contact structure 1634 form a second segment of the zig-zag course extending along another lateral direction counterclockwise tilted from the Y-direction with a second acute angel; and so on.

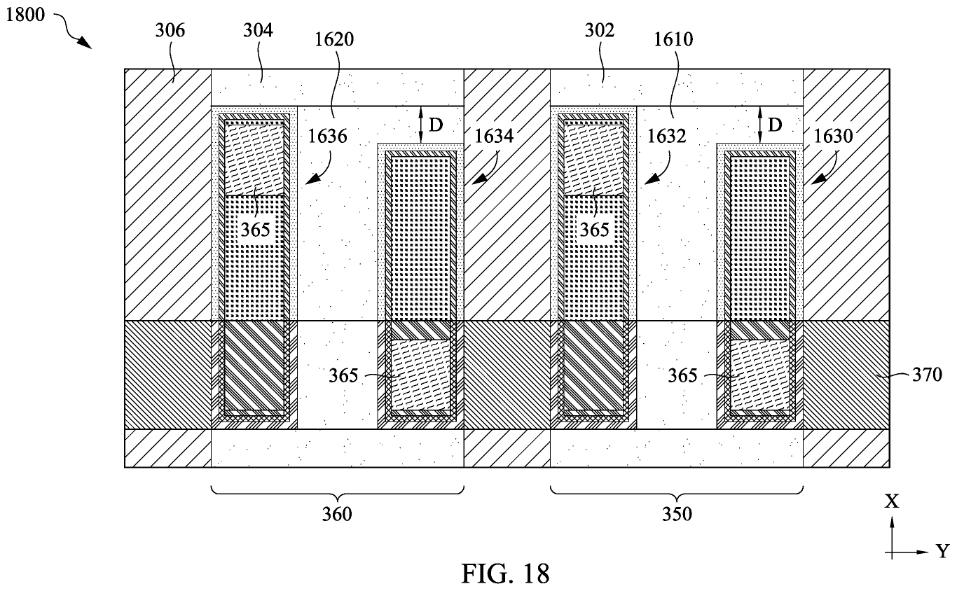

Referring next to FIG. 18, the layout 1800 is substantially similar to the layout 1700 except that some of the slot-like contact structures 1630 to 1636 have shorter longitudinal length than others of the slot-like contact structures 1630 to 1636. Specifically, such shorter contact structures may each have at least one end not aligned with the side of the corresponding semiconductor layer 1610 or 1620. For example in FIG. 18, the contact structures 1630 and 1634 are each formed shorter than any of the contact structures 1632 and 1636. Each of the contact structures 1632 and 1636 may extend from one side of the semiconductor layer 1610 or 1620 to its other opposite side, while each of the contact structures 1630 and 1634 may extend from one side of the semiconductor layer 1610 or 1620 with a length that is less than a width of the corresponding semiconductor layer (extending in the X-direction) by a distance “D.” Alternatively stated, one end of each of the contact structures 1630 and 1634 is aligned with one side of the semiconductor layer 1610 or 1620, while its other end is shifted from the other side of the corresponding semiconductor layer with a distance (D).

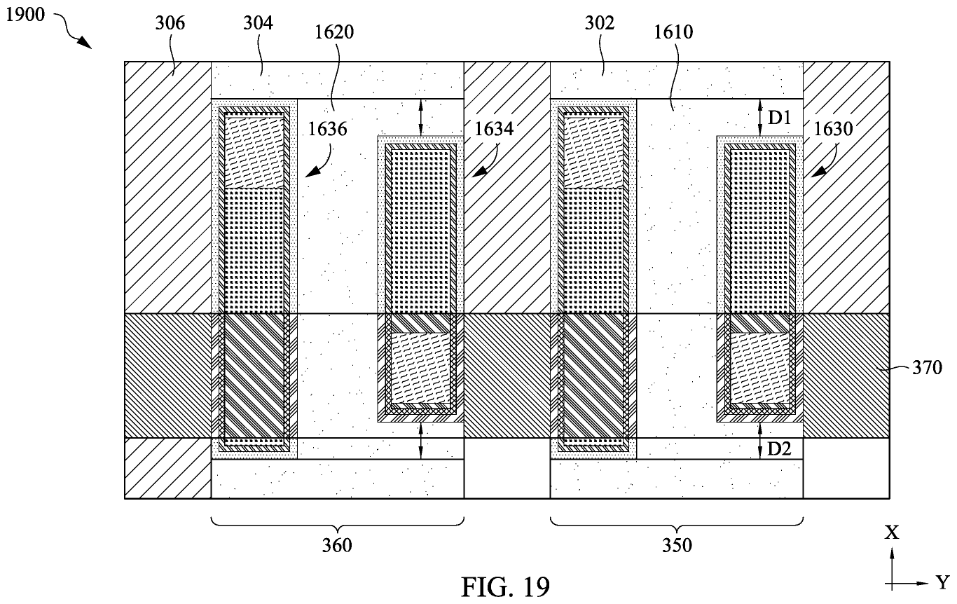

Referring next to FIG. 19, the layout 1900 is substantially similar to the layout 1700 except that some of the slot-like contact structures 1630 to 1636 have shorter longitudinal length than others of the slot-like contact structures 1630 to 1636. Specifically, such shorter contact structures may each have at least one end not aligned with the side of the semiconductor layer 1610 or 1620. For example in FIG. 19, the contact structures 1630 and 1634 are each formed shorter than any of the contact structures 1632 and 1636. Each of the contact structures 1632 and 1636 may extend from one side of the semiconductor layer 1610 or 1620 to its other opposite side, while each of the contact structures 1630 and 1634 may extend along the X-direction with a length that is less than a width of the semiconductor layer 1610 or 1620 (extending in the X-direction) by a first distance “D₁” and a second distance “D₂.” Alternatively stated, one end of each of the contact structures 1630 and 1634 is shifted from one side of the semiconductor layer 1610 or 1620 with a first distance (D₁), and its other end is shifted from the other side of the semiconductor layer 1610 or 1620 with a second distance (D₂).

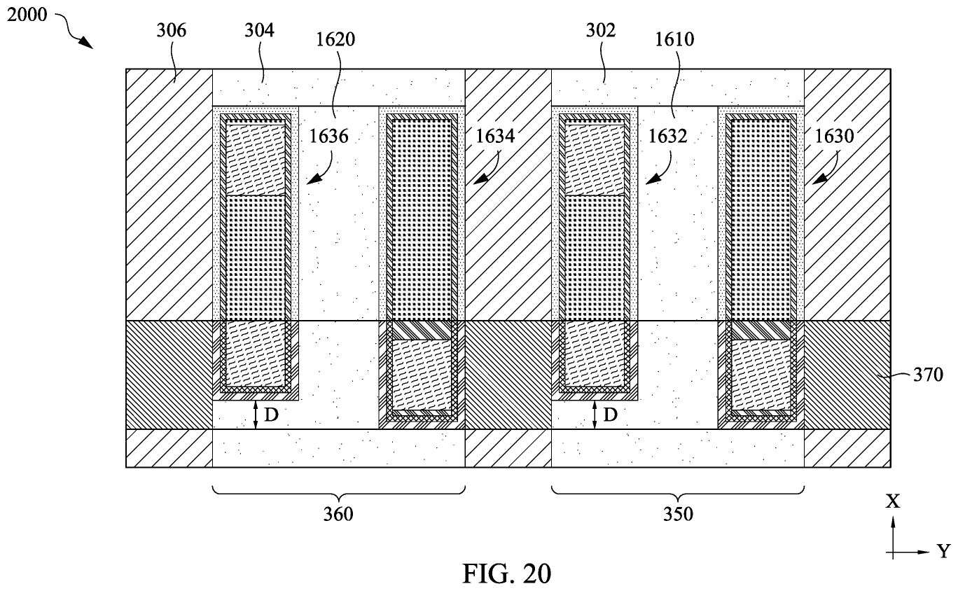

Referring next to FIG. 20, the layout 2000 is substantially similar to the layout 1700 except that some of the slot-like contact structures 1630 to 1636 have shorter longitudinal length than others of the slot-like contact structures 1630 to 1636. Specifically, such shorter contact structures may each have at least one end not aligned with the side of the corresponding semiconductor layer 1610 or 1620. For example in FIG. 20, the contact structures 1632 and 1636 are each formed shorter than any of the contact structures 1630 and 1634. Each of the contact structures 1630 and 1634 may extend from one side of the semiconductor layer 1610 or 1620 to its other opposite side, while each of the contact structures 1632 and 1636 may extend from one side of the semiconductor layer 1610 or 1620 with a length that is less than a width of the corresponding semiconductor layer (extending in the X-direction) by a distance “D.” Alternatively stated, one end of each of the contact structures 1632 and 1636 is aligned with one side of the semiconductor layer 1610 or 1620, while its other end is shifted from the other side of the corresponding semiconductor layer with a distance (D).

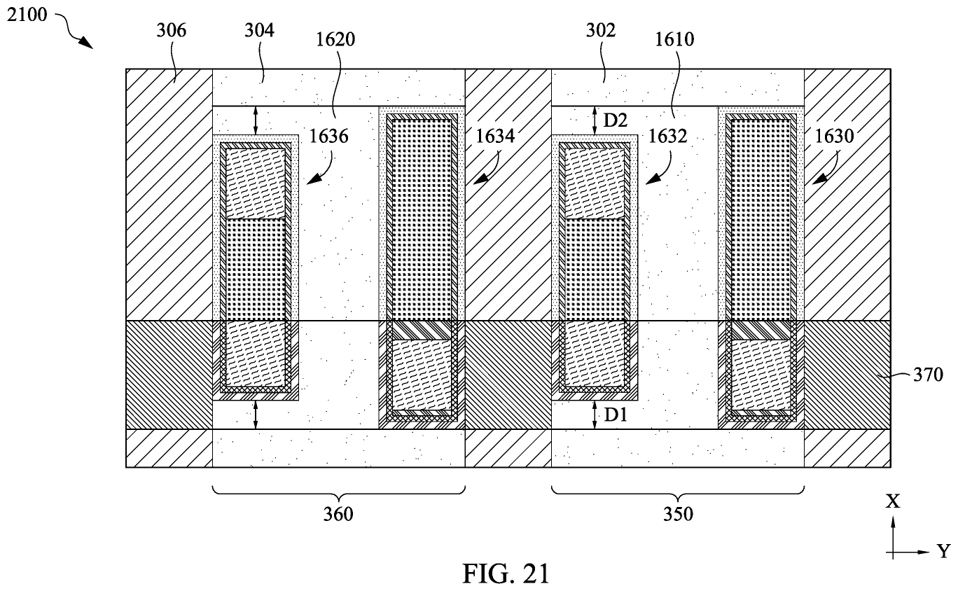

Referring next to FIG. 21, the layout 2100 is substantially similar to the layout 1700 except that some of the slot-like contact structures 1630 to 1636 have shorter longitudinal length than others of the slot-like contact structures 1630 to 1636. Specifically, such shorter contact structures may each have at least one end not aligned with the side of the semiconductor layer 1610 or 1620. For example in FIG. 21, the contact structures 1632 and 1636 are each formed shorter than any of the contact structures 1630 and 1634. Each of the contact structures 1630 and 1634 may extend from one side of the semiconductor layer 1610 or 1620 to its other opposite side, while each of the contact structures 1632 and 1636 may extend along the X-direction with a length that is less than a width of the semiconductor layer 1610 or 1620 (extending in the X-direction) by a first distance “D₁” and a second distance “D₂.” Alternatively stated, one end of each of the contact structures 1632 and 1636 is shifted from one side of the semiconductor layer 1610 or 1620 with a first distance (D₁), and its other end is shifted from the other side of the semiconductor layer 1610 or 1620 with a second distance (D₂).

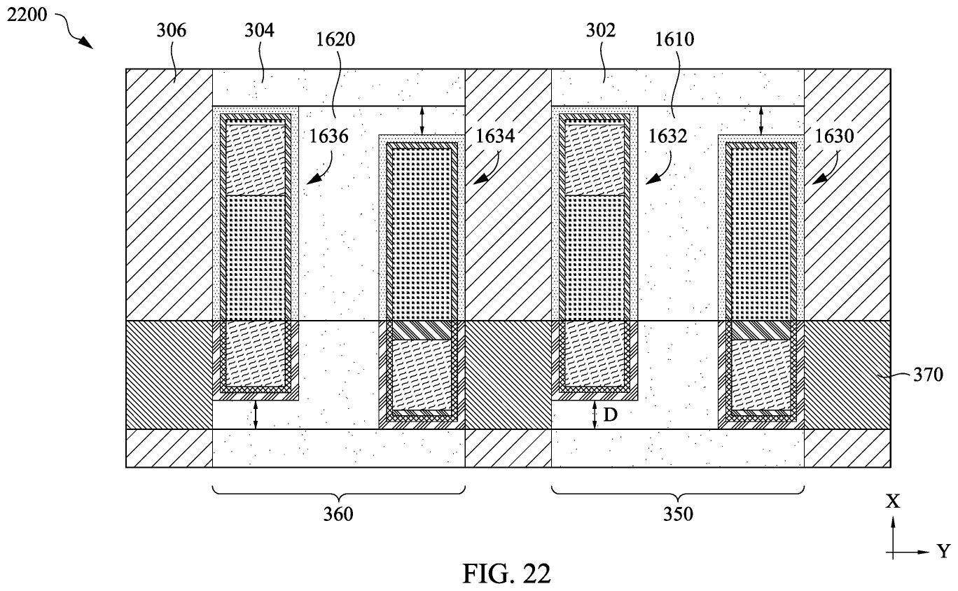

Referring next to FIG. 22, the layout 2200 is substantially similar to the layout 1700 except that each of the slot-like contact structures 1630 to 1636 is formed shorter than the underlying semiconductor layer 1610 or 1620 along the X-direction. Specifically, such shorter contact structures may each have its one end not aligned with one side of the semiconductor layer 1610 or 1620, while the other end is aligned with the other side of the semiconductor layer 1610 or 1620. For example in FIG. 22, each of the contact structures 1630 to 1636 may extend from one side of the semiconductor layer 1610 or 1620 with a length that is less than a width of the semiconductor layer (extending in the X-direction) by a distance “D.” Alternatively stated, one end of each of the contact structures 1630 to 1636 is aligned with one side of the semiconductor layer 1610 or 1620, while its other end is shifted from the other side of the semiconductor layer 1610 or 1620 with a distance (D).

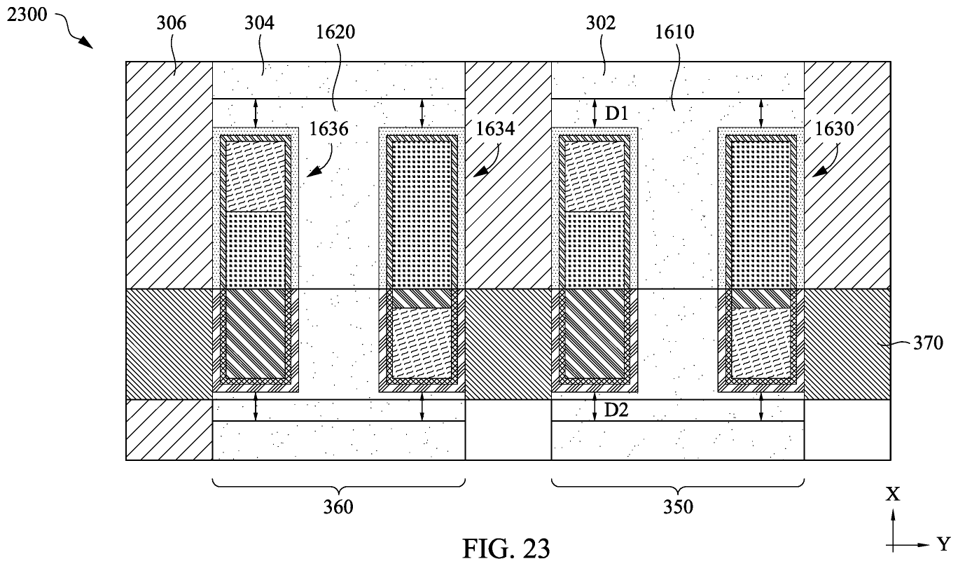

Referring next to FIG. 23, the layout 2300 is substantially similar to the layout 1700 except that each of the slot-like contact structures 1630 to 1636 is formed shorter than the underlying semiconductor layer 1610 or 1620 along the X-direction. Specifically, such shorter contact structures may each have its both ends not aligned with any side of the semiconductor layer 1610 or 1620. For example in FIG. 23, each of the contact structures 1630 to 1636 may extend in the X-direction with a length that is less than a width of the semiconductor layer 1610 or 1620 (extending in the X-direction) by a first distance “D₁” and a second distance “D₂.” Alternatively stated, one end of each of the contact structures 1630 to 1636 is shifted from one side of the semiconductor layer 1610 or 1620 with a first distance (D₁), while its other end is shifted from the other side of the corresponding semiconductor layer with a second distance (D₂).

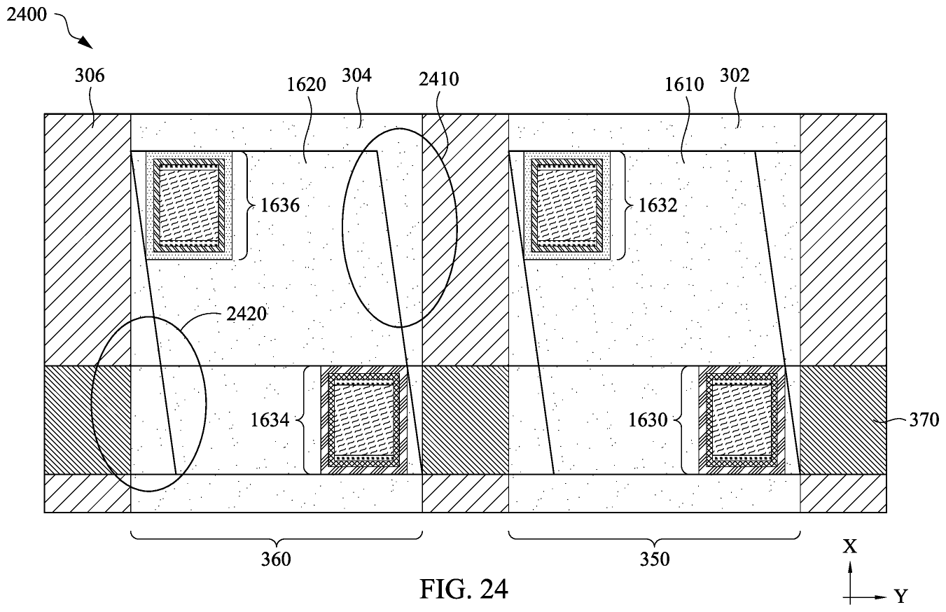

Referring next to FIG. 24, the layout 2400 is substantially similar to the layout 1600 except that each of the semiconductor layer 1610 and 1620 is formed in a parallelogram shape. With the semiconductor layer 1610 and 1620 being formed in such a parallelogram shape, some portions of the underlying metal layer 302 or 304 may not be covered by the semiconductor layer 1610 or 1620, as indicated by 2410 and 2420 in FIG. 24. As such, leakage current in such areas may be further reduced.

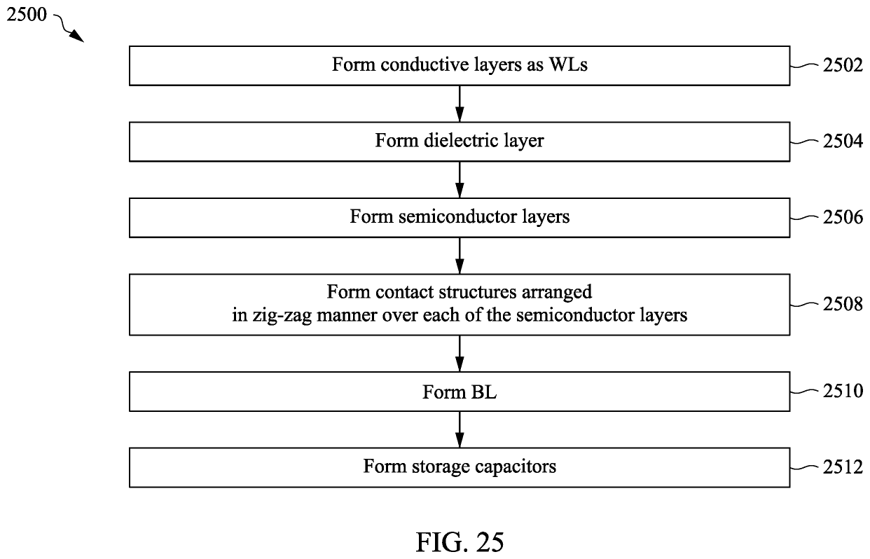

FIG. 25 illustrates a flowchart of a method 2500 to form a memory device, according to various embodiments of the present disclosure. For example, at least some of the operations (or steps) of the method 2500 can be performed to fabricate, make, or otherwise form a memory device (e.g., 300 of FIGS. 3-4). Accordingly, the following discussion of the method 2500 may refer to some of the reference numerals used in FIG. 3 as a non-limiting example. Further, the method 2500 is merely an example, and is not intended to limit the present disclosure. It should thus be understood that additional operations may be provided before, during, and after the method 2500 of FIG. 25, and that some other operations may only be briefly described herein.

The method 2500 starts with operation 2502 of forming a number of metal layers. In some embodiments, these conductive layers (e.g., 302, 304) may be formed during BEOL processing. For example, these conductive layers 302-304 may be embedded in the IMD material of a corresponding one of multiple metallization layers (e.g., M0, M1, etc.) disposed above a semiconductor substrate. In some embodiments, the conductive layers 302-304 are arranged in parallel with each other, i.e., all extending along a first lateral direction (e.g., the X-direction). Each of the conductive layers 302-304 may operatively serve as a word line WL of a memory array, or a common gate terminal of plural memory cells of the memory array that are arranged along the same row.

Next, the method 2500 proceeds to operation 2504 of forming a dielectric layer. In some embodiments, the dielectric layer (e.g., 306) may be universally formed over the different conductive layers 302-304. In some embodiments, the dielectric layer 306 may operatively serve as a gate dielectric for the plural memory cells of the memory array.

Next, the method 2500 proceeds to operation 2506 of forming a number of semiconductor layers. In some embodiments, these semiconductor layers (e.g., 308, 310) may be formed over dielectric layer 306. The semiconductor layers 308-310 are arranged in parallel with each other, i.e., all extending along a second lateral direction (e.g., the Y-direction). Each of the semiconductor layers 308-310 may operatively serve as channels of plural memory cells of the memory array that are arranged along the same column.

Next, the method 2500 proceeds to operation 2508 of forming a number of contact structures over a corresponding one of the semiconductor layers that are arranged in a zig-zag manner. In some embodiments, over each of the semiconductor layer (e.g., 308), a number of contact structures (e.g., 320 to 328) are formed in a zig-zag manner. For example, a first set of the contact structures (e.g., 320, 324, 328) are disposed along one side of the semiconductor layer 308, and a second set of the contact structures (e.g., 322, 326) are disposed along the other side of the semiconductor layer 308. Further, each of the second set of the contact structures is interposed between neighboring ones of the first set of the contact structures along a longitudinal direction of the semiconductor layer 308.

In some embodiments, the first set of the contact structures may operatively serve as drain terminals of plural memory cells of the memory array that are arranged along the same column, while the second set of the contact structures may operatively serve as source terminal of those memory cells. Further, each memory cell may include three of these contact structures, e.g., one of the second set of contact structures (which functioning as a common source terminal of the memory cell) and two of the first set of contact structures (which functioning as respective drain terminals of the memory cell).

Next, the method 2500 proceeds to operation 2510 of forming a bit line BL. In some embodiments, the bit line BL (e.g., 370) may be coupled to the drain terminals of the memory cells that are arranged along the same column. As such, the bit line BL may extend along the same direction as the underlying semiconductor layer.

Next, the method 2500 proceeds to operation 2512 of forming a number of storage capacitors. In some embodiments, each of the storage capacitors is connected to the source terminal of the corresponding memory cell formed below. Further, each of the storage capacitors may be formed as an MIM structure.

In one aspect of the present disclosure, a semiconductor device is disclosed. The semiconductor device includes a conductive layer extending along a first lateral direction; a gate dielectric layer disposed over the conductive layer; a channel layer disposed over the gate dielectric layer and extending along a second lateral direction perpendicular to the first lateral direction; a first via-like structure, in direct contact with the channel layer, that is disposed along a first edge of the first channel extending along the second lateral direction; and a second via-like structure, in direct contact with the channel layer, that is disposed along a second, opposite edge of the first channel extending along the second lateral direction. The first via-like structure and second via-like structure are laterally separated apart along a third lateral direction that is clockwise tilted from the second lateral direction with a first positive angle.

In another aspect of the present disclosure, a memory device is disclosed. The memory device includes a plurality of first memory cells arranged along a first lateral direction; and a plurality of second memory cells arranged along the first lateral direction and separated apart from the plurality of first memory cells along a second lateral direction perpendicular to the first lateral direction. Each of the plurality of first and second memory cells comprises a first via-like structure; and a second via-like structure. The first via-like structure and second via-like structure are laterally separated apart along a third lateral direction that is clockwise tilted from the first lateral direction with a first positive angle.

In yet another aspect of the present disclosure, a memory device is disclosed. The memory device includes a conductive layer extending along a first lateral direction; a gate dielectric layer disposed over the conductive layer; a first channel layer disposed over the gate dielectric layer and extending along a second lateral direction perpendicular to the first lateral direction; and a second channel layer disposed over the gate dielectric layer and extend in parallel with the first channel layer. A plurality of first memory cells are at least partially formed by the conductive layer, the gate dielectric layer, and the first channel layer; and a plurality of second memory cells are at least partially formed by the conductive layer, the gate dielectric layer, and the second channel layer. Each of the plurality of first and second memory cells comprises a first via-like structure; and a second via-like structure. The first via-like structure and second via-like structure are laterally separated apart along a third lateral direction that is clockwise tilted from the first lateral direction with a first positive angle.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a conductive layer extending along a first lateral direction;
a gate dielectric layer disposed over the conductive layer;
a channel layer disposed over the gate dielectric layer and extending along a second lateral direction perpendicular to the first lateral direction;
a first via-like structure, in direct contact with the channel layer, that is disposed along a first edge of the first channel extending along the second lateral direction; and
a second via-like structure, in direct contact with the channel layer, that is disposed along a second, opposite edge of the first channel extending along the second lateral direction;
wherein the first via-like structure and second via-like structure are laterally separated apart along a third lateral direction that is clockwise tilted from the second lateral direction with a first positive angle.

2. The semiconductor device of claim 1, further comprising:
a third via-like structure, in direct contact with the channel layer, that is disposed along the first edge of the first channel;
wherein the second via-like structure and the third via-like structure are laterally separated apart along a fourth lateral direction that is counterclockwise tilted from the second lateral direction with a second positive angle.

3. The semiconductor device of claim 2, wherein, when viewed from the top, the second via-like structure is disposed around a middle portion of the conductive layer, while the first via-like structure and third via-like structure are disposed around opposite edges of the conductive layer extending along the first lateral direction, respectively.

4. The semiconductor device of claim 3, further comprising a capacitor disposed above and in electrical connection with the second via-like structure.

5. The semiconductor device of claim 4, wherein the conductive layer, the gate dielectric layer, the channel layer, the first to third via-like structures, and the capacitor collectively form a single memory bit cell.

6. The semiconductor device of claim 1, wherein, when viewed from the top, the first via-like structure and second via-like structure are disposed around opposite edges of the conductive layer extending along the first lateral direction, respectively.

7. The semiconductor device of claim 6, further comprising a capacitor disposed above and in electrical connection with the second via-like structure.

8. The semiconductor device of claim 7, wherein the conductive layer, the gate dielectric layer, the channel layer, the first and second via-like structures, and the capacitor collectively form a single memory bit cell.

9. The semiconductor device of claim 1, wherein the channel layer includes a bottom portion, a middle portion, and a top portion, and wherein the bottom, middle, and top portions have respectively different doping concentrations.

10. The semiconductor device of claim 9, wherein the top portion surrounds a bottom surface and sidewalls of each of the first and second via-like structures.

11. A memory device, comprising:
a plurality of first memory cells arranged along a first lateral direction; and
a plurality of second memory cells arranged along the first lateral direction and separated apart from the plurality of first memory cells along a second lateral direction perpendicular to the first lateral direction;
wherein each of the plurality of first and second memory cells comprises:
a first via-like structure; and
a second via-like structure;
wherein the first via-like structure and second via-like structure are laterally separated apart along a third lateral direction that is clockwise tilted from the first lateral direction with a first positive angle.

12. The memory device of claim 11, further comprising:
a first bit line extending along the first lateral direction and in electrical connection with the first via-like structure of each of the plurality of first memory cells; and
a second bit line extending along the first lateral direction and in electrical connection with the first via-like structure of each of the plurality of second memory cells.

13. The memory device of claim 11, wherein each of the plurality of first and second memory cells further comprises a third via-like structure, wherein the second via-like structure and the third via-like structure are laterally separated apart along a fourth lateral direction that is counterclockwise tilted from the first lateral direction with a second positive angle.

14. The memory device of claim 13, wherein the first and second positive angles are each less than 90 degrees.

15. The memory device of claim 11, wherein each of the plurality of first and second memory cells further comprises:
a transistor; and
a capacitor.

16. The memory device of claim 15, wherein a first end of the transistor is connected to the first via-like structure, and a second end of the transistor is coupled to the capacitor through the second via-like structure.

17. The memory device of claim 15, wherein the transistor and the capacitor are formed in a back-end-of-line (BEOL) network formed over a semiconductor substrate.

18. A memory device, comprising:
a conductive layer extending along a first lateral direction;
a gate dielectric layer disposed over the conductive layer;
a first channel layer disposed over the gate dielectric layer and extending along a second lateral direction perpendicular to the first lateral direction; and
a second channel layer disposed over the gate dielectric layer and extend in parallel with the first channel layer;
wherein a plurality of first memory cells are at least partially formed by the conductive layer, the gate dielectric layer, and the first channel layer; and a plurality of second memory cells are at least partially formed by the conductive layer, the gate dielectric layer, and the second channel layer;
wherein each of the plurality of first and second memory cells comprises:
a first via-like structure; and
a second via-like structure;
wherein the first via-like structure and second via-like structure are laterally separated apart along a third lateral direction that is clockwise tilted from the first lateral direction with a first positive angle.

19. The memory device of claim 18, wherein each of the plurality of first and second memory cells further comprises a third via-like structure, wherein the second via-like structure and the third via-like structure are laterally separated apart along a fourth lateral direction that is counterclockwise tilted from the first lateral direction with a second positive angle.

20. The memory device of claim 19, wherein the first and second positive angles are each less than 90 degrees.
